(19) United States
(12) Patent Application Publication
(10) Pub. No.: US 2019/0318860 A1
(43) Pub. Date: Oct. 17, 2019

(54) IRON-ALUMINUM ALLOY MAGNETIC THIN FILM

(71) Applicants: THE BOARD OF TRUSTEES OF THE UNIVERSITY OF ALABAMA, Tuscaloosa, AL (US); TDK CORPORATION, Tokyo (JP)

(72) Inventors: Takao SUZUKI, Tuscaloosa, AL (US); Tim MEWES, Northport, AL (US); Gary J. MANKEY, Tuscaloosa, AL (US); Isao KANADA, Tokyo (JP); Yusuke ARIAKE, Tokyo (JP)

(21) Appl. No.: 16/345,351

(22) PCT Filed: Apr. 20, 2017
(86) PCT No.: PCT/US2017/028514

§ 371 Date: Apr. 26, 2019

Related U.S. Application Data
(60) Provisional application No. 62/413,582, filed on Oct. 27, 2016.

(51) Int. Cl. H01F 10/14; C22C 38/10; C22C 38/06; C23C 14/18; C23C 14/35; C23C 14/16; C30B 23/02; C30B 29/52; H01F 41/18

(52) U.S. Cl. CPC H01F 10/14; C22C 38/10; C22C 38/06; C23C 14/185; C22C 2202/02; C23C 14/165; C30B 23/025; C30B 29/52; H01F 41/18; C23C 14/35

(57) ABSTRACT

An Fe—Al alloy magnetic thin film according to the present invention contains, in terms of atomic ratio, 0% to 35% (inclusive of 0%) of Co and 1.5% to 2% of Al. A direction of a crystal contained in a material is perpendicular to a substrate surface and a crystallite size is 150 Å or less. Methods of making and using said thin film are also disclosed.

### CROSS REFERENCE TO RELATED APPLICATIONS

This application claims the benefit of priority to U.S. Provisional Application 62/413,582, filed Oct. 27, 2016, which is incorporated by reference herein in its entirety.

### FIELD

The present invention generally relates to soft magnetic materials for use in, e.g., a high-frequency range including the gigahertz range and, in particular, to an iron (Fe)-aluminum (Al)-based magnetic thin film that has high magnetization and small damping parameter and coercive force.

### BACKGROUND

As the capacity and speed provided by communication technology increase, magnetic materials used in electronic parts such as inductors, low-pass filters, and bandpass filters are increasingly required to have high magnetic permeability and low magnetic loss in a high-frequency band such as the gigahertz band. Typical causes of loss in soft magnetic materials are hysteresis loss, eddy current loss, and residual loss.

Hysteresis loss is proportional to the area of magnetic hysteresis. Thus, decreasing the coercive force decreases the area of magnetic hysteresis and thereby decreases the hysteresis loss.

In order to decrease eddy current loss, increasing the electrical resistance of a magnetic material and, if a thin film is to be magnetized in an in-plane direction, decreasing the thickness of the thin film are known to be effective for decreasing the eddy current loss.

Residual loss refers to any loss other than hysteresis loss and eddy current loss. An example of the residual loss is a loss caused by resonance phenomena, such as domain-wall resonance and resonance caused by rotation magnetization (ferromagnetic resonance). In order to inhibit domain-wall resonance, it is effective to decrease the size of crystals of the magnetic material to a critical single-domain grain size or smaller so as to eliminate the domain walls. For iron isotropic crystals, the critical single-domain grain size is about 280 Å.

The loss attributable to resonance caused by rotation magnetization can be decreased by narrowing the resonance linewidth since narrowing the resonance linewidth will cause loss to occur only at the resonance frequency and frequencies very close to the resonance frequency. In general, in a frequency dependence of magnetic permeability, resonance caused by rotation magnetization has a linewidth that is proportional to a damping parameter α. Thus, controlling the damping parameter at a small value will suppress broadening of the resonance peak and achieve low-loss in a wide range of frequency bands.

Bijoy K., et al., “Relaxation in epitaxial Fe films measured by ferromagnetic resonance,” J. Appl. Phys. 95 (11):6610-6612, 2004, discloses measurement of ferromagnetic resonance of an iron thin film prepared by molecular beam epitaxy. As the thickness of the thin film decreases, the resonance linewidth gradually increases due to external factors such as surface roughness. It is reported in the document that the intrinsic damping parameter of the material predicted by eliminating the influence of external factors is 0.003 with respect to the frequency linewidth and 0.0043 with respect to the magnetic field linewidth. The influential external factors are surface roughness, defects in the material, and orientation of the crystals. Controlling these factors is critical.

In order to obtain high magnetic permeability, it is well known that intensifying magnetization is effective.

What are thus needed are new magnetic materials that have large magnetization and small damping parameters and coercive force suitable for use in high-frequency (e.g., gigahertz) electronic parts. Method of preparing such materials and devices containing them are also needed. The compositions, methods, and devices disclosed herein address these and other needs.

### SUMMARY

The present invention provides a magnetic material having large magnetization and small damping parameter and coercive force suitable for use in high-frequency electronic parts. In certain aspects, disclosed is an Fe—Al alloy magnetic thin film comprising, in terms of atomic ratio, 0% to 35% (inclusive of 0%) of Co and 1.5% to 2% of Al, in which a <110> direction of a crystal contained in a material is perpendicular to a substrate surface and a crystallite size is 150 Å or less. Additional magnetic materials that have large magnetization and small damping parameter and coercive force suitable for use in the gigahertz band are disclosed. Methods of making the disclosed magnetic materials and devices that can contain them are also disclosed.

Additional advantages will be set forth in part in the description that follows, and in part will be obvious from the description, or may be learned by practice of the aspects described below. The advantages described below will be realized and attained by means of the elements and combinations particularly pointed out in the appended claims. It is to be understood that both the foregoing general description and the following detailed description are exemplary and explanatory only and are not restrictive.

### DETAILED DESCRIPTION

The present invention will now be described in detail. It should be understood that the scope of the present invention is not limited to the examples below of implementing the present invention (such examples are referred to as “embodiments”). The structural features of the present invention are not limited to the embodiments described below and features easily conceivable by a person skilled in the art, substantially identical features, and equivalent features are all part of the structural features of the present invention.

### Magnetic Materials

Disclosed herein is an Fe—Al alloy magnetic thin film comprising, in terms of atomic ratio, 0% to 35% (inclusive of 0%) of Co and 1.5% to 2% of Al, and has an average crystallite size of 150 Å or less. Moreover, the <110> direction of the crystal is perpendicular to a surface of the substrate. For example, the Fe—Al alloy magnetic thin film can have 0% or more Co (e.g., 5% or more, 10% or more, 15% or more, 20% or more, 25% or more, or 30% or more). In other examples, the Fe—Al alloy magnetic thin film can have 35% or less Co (e.g., 30% or less, 25% or less, 20% or less, 15% or less, 10% or less, or 5% or less). In still further examples, the Fe—Al allow magnetic thin film can have 0%, 5%, 10%, 15%, 20%, 25%, 30%, or 35% Co, where any of the stated values can form an upper or lower endpoint of a range. In some examples, the Fe—Al alloy magnetic thin film can have 1.5% or more of Al (e.g., 1.6% or more, 1.7% or more, 1.8% or more, or 1.9% or more). In some examples, the Fe—Al alloy magnetic thin film can have 2% or less of Al (e.g., 1.9% or less, 1.8% or less, 1.7% or less, or 1.6% or less). In still further examples, the Fe—Al alloy magnetic thin film can have 1.5%, 1.6%, 1.7%, 1.8%, 1.9%, or 2% Al, where any of the stated values can form an upper or lower endpoint of a range. In some examples, the Fe—Al magnetic thin film can have an average crystallite size of 150 Å or less (e.g., 125 Å or less, 100 Å or less, 75 Å or less, 50 Å or less, or 25 Å or less). The Fe—Al alloy magnetic thin film has good magnetic properties, namely, a damping parameter less than 0.01 (e.g., 0.009 or less, 0.008 or less, 0.006 or less, 0.005 or less, 0.004 or less, 0.003 or less, 0.002 or less, or 0.001 or less) and a coercive force less than 100 Oe (e.g., 90 Oe or less, 80 Oe or less, 70 Oe or less, 60 Oe or less, 50 Oe or less, 40 Oe or less, 30 Oe or less, 20 Oe or less, or 10 Oe or less).

### Methods for Producing Magnetic Material

An embodiment of the present invention is produced as follows. First, a target material is prepared as a raw material. Single-element targets of Fe, Co, and Al can be used or a target material whose composition is adjusted to prepare a thin film having the intended composition can be used. A combination of two or more alloy targets or a combination of an alloy target and a single-element target can be used as long as the composition can be adjusted to the desired composition. In such a case, the alloy target can be any one of an Fe—Co—Al alloy target, an Fe—Co alloy target, an Fe—Al alloy target, or a Co—Al alloy target. Since oxygen decreases the saturation magnetization of the magnetic material and increases the coercive force, the oxygen content of the target material is preferably as low as possible.

The substrate used in sputter-deposition of the film can be composed of any of various metals, glass, silicon, or ceramic but is preferably not reactive to Fe, Co, Al, Fe—Co—Al alloy, Fe—Co alloy, Fe—Al alloy, or Co—Al alloy.

The vacuum chamber of the film fabrication apparatus in which sputtering is conducted preferably contains as little impurity elements, such as oxygen, as possible. The vacuum chamber is preferably evacuated to 10⁻⁵ Torr or less, and more preferably 10⁻⁶ Torr or less.

In order to expose a clean surface of the target material before film deposition, thorough preliminary sputtering is preferably conducted. Thus, the film fabrication apparatus is preferably equipped with a blocking mechanism disposed between the substrate and the target and configured to be operable in a vacuum state. The sputtering technique is preferably magnetron sputtering and the atmosphere gas is Ar, which is unreactive to the magnetic material. The sputtering power supply may be a DC or RF power supply and appropriate choice may be made according to the target material.

The film is deposited by using the target material and substrate described above. Examples of the film deposition method include a co-sputtering method by which plural targets are used simultaneously to deposit plural components at the same time and a multilayer film method by which plural targets are used one by one in a particular order to form a multilayer film.

According to the multilayer film method, an appropriate combination of target materials necessary for obtaining the intended composition is selected from Fe, Co, Al, Fe—Co—Al alloy, Fe—Co alloy, Fe—Al alloy, and Co—Al alloy and deposition is repeated to form layers in a particular order to a particular thickness. When an oxide of an element having a higher standard free energy of formation of an oxide than Al, such as SiO₂ glass, is used, Fe, Co, or Fe or Co alloy free of Al is preferably deposited first in forming films in order to prevent oxidation of Al. When an oxide of an element that has a higher standard free energy of formation of an oxide than Fe is used, the reactivity with samples must be confirmed in advance before use.

The thickness of the Fe—Al-based magnetic thin film according to the present invention can be set to a desired thickness by adjusting the deposition rate, time, argon atmosphere pressure, and the number of times film deposition is conducted if the film is formed by a multilayer film method. In order to adjust the thickness, the relationship between the deposition conditions and the thickness has to be investigated in advance. Typically, the thickness is measured by contact profilometry, X-ray reflectometry, polarized-light microscopy (ellipsometry), quartz crystal microbalance, or the like.

When the substrate is heated during sputtering, strain in the film is decreased and the coercive force tends to be low. An alloy thin film can still be obtained without heating by employing the multilayer film method and adjusting the thickness of each layer to 50 Å or less (e.g., 40 Å or less, 30 Å or less, 20 Å or less, or 10 Å or less). Whether the substrate is to be heated may be appropriately selected according to the properties required for the electronic part. Heat can be applied after film deposition in order to eliminate strain. Heating performed during and after deposition is preferably performed in inert gas, such as argon, or in vacuum so as not to oxidize the sample.

A protective layer made of Mo, W, Ru, Ta, or the like can be formed on top of the Fe—Al alloy magnetic thin film according to the present invention in order to prevent oxidation of the magnetic thin film.

### EXAMPLES

The following examples are set forth below to illustrate the methods and results according to the disclosed subject matter. These examples are not intended to be inclusive of all aspects of the subject matter disclosed herein, but rather to illustrate representative methods and results. These examples are not intended to exclude equivalents and variations of the present invention which are apparent to one skilled in the art.

Efforts have been made to ensure accuracy with respect to numbers (e.g., amounts, temperature, etc.) but some errors and deviations should be accounted for. Unless indicated otherwise, parts are parts by weight, temperature is in ° C. or is at ambient temperature, and pressure is at or near atmospheric. There are numerous variations and combinations of reaction conditions, e.g., component concentrations, temperatures, pressures and other reaction ranges and conditions that can be used to optimize the product purity and yield obtained from the described process. Only reasonable and routine experimentation will be required to optimize such process conditions.

Fe, Fe-34 at % Co, and Al were used as target materials. A single crystal MgO substrate (MgO(100) substrate) having a (100) surface and a SiO₂ glass substrate were used as the substrate for film deposition.

An apparatus capable of being evacuated to 10⁻⁷ Torr and equipped with plural sputtering mechanisms housed in the same chamber was used as the film fabrication apparatus. The target materials described above and a Ru target material for forming a protective film were loaded into the film fabrication apparatus. The magnetron sputtering technique was used for sputtering. In heating the substrate during film deposition, radiant heat of a halogen lamp was used and the substrate temperature was kept at 150° C. The base pressure before introduction of argon was 2×10⁻⁷ Torr in the absence of heating and 1.5×10⁻⁶ Torr in the presence of heating. Film deposition was conducted in a 4 mTorr argon atmosphere. Power supplied to the sputtering gun and the deposition time were adjusted to control the deposition rate and the thickness.

### Sample Preparation

As indicated in Table 1, Examples 1, 2, 13, and 14 concern Fe—Al alloy magnetic thin films free of Co. An Fe layer 1.8 Å in thickness and an Al layer 0.4 Å in thickness were alternately deposited each a particular number of times on a SiO₂ glass or MgO(100) substrate and then a Ru protective layer having a thickness of 50 Å was formed. In preparing samples of Examples 1 and 2, substrate heating was not performed. In the absence of heating, the substrate temperature was presumably about 70° C. to 80° C. during deposition. In preparing Examples 13 and 14, deposition was conducted while heating the substrate to 150° C.

Samples of Examples 3 to 12 and 15 to 20 are Fe—Al alloy magnetic thin films containing Co. The composition of each film was controlled by varying the thickness of each Fe layer in the range of 0 to 1.8 Å, varying the thickness of each Fe—Co layer in the range of 0 to 1.8 Å, and adjusting the thickness of the Al layer to 0.4 Å. Deposition of Fe, deposition of Fe-34 at % Co alloy, and deposition of Al were repeated in that order a predetermined number of times on a SiO₂ glass or MgO(100) substrate and then a Ru protective layer having a thickness of 50 Å was formed. In Examples 3 to 12, samples were prepared without substrate heating. In the absence of heating, the substrate temperature was presumably about 70° C. to 80° C. during deposition. In preparing samples of Examples 15 to 20, deposition was conducted while heating the substrate to 150° C.

### Structural Evaluation

The thickness of the film of each sample was determined by X-ray reflectometry. The diffraction pattern was measured in the 2θ range of 25° to 90° by X-ray diffractometry and the diffraction peak position of each sample was determined by a half-value-width midpoint method. The obtained peak position was used to identify the generated phase and determine the lattice constant. The crystallite size was calculated from the full width at half maximum of the diffraction peak of each sample by using the Scherrer's equation. The results are shown in Table 1.

TABLE 1

| | | | | | | | Peak | Lattice | Crystallite |
|---|---|---|---|---|---|---|---|---|---|
| | Fe | Co | Al | | Substrate | Thickness | position 2θ | constant | size × 10² |
| | (at %) | (at %) | (at %) | Substrate | heating | (Å) | (degree) | (Å) | (Å) |
| Example 1 | 98.2 | 0.0 | 1.8 | SiO2 glass | Ambient | 520 | 44.66 | 2.87 | 1.2 |
| Example 2 | 98.2 | 0.0 | 1.8 | MgO (100) | Ambient | 530 | | | |
| Example 3 | 91.1 | 7.4 | 1.6 | SiO2 glass | Ambient | 550 | 44.69 | 2.87 | 1.1 |
| Example 4 | 91.1 | 7.4 | 1.6 | MgO (100) | Ambient | 550 | | | |
| Example 5 | 80.4 | 17.9 | 1.7 | SiO2 glass | Ambient | 540 | 44.84 | 2.86 | 0.9 |
| Example 6 | 80.4 | 17.9 | 1.7 | MgO (100) | Ambient | 550 | | | |
| Example 7 | 73.8 | 24.4 | 1.8 | SiO2 glass | Ambient | 550 | 44.87 | 2.86 | 0.8 |
| Example 8 | 73.8 | 24.4 | 1.8 | MgO (100) | Ambient | 550 | | | |
| Example 9 | 68.6 | 29.8 | 1.6 | SiO2 glass | Ambient | 530 | 44.89 | 2.86 | 1.1 |
| Example 10 | 68.6 | 29.8 | 1.6 | MgO (100) | Ambient | 530 | | | |
| Example 11 | 64.7 | 33.8 | 1.5 | SiO2 glass | Ambient | 540 | 44.95 | 2.85 | 1.4 |
| Example 12 | 64.7 | 33.8 | 1.5 | MgO (100) | Ambient | 530 | | | |
| Example 13 | 98.4 | 0.0 | 1.6 | SiO2 glass | 150° C. | 610 | | | |
| Example 14 | 98.4 | 0.0 | 1.6 | MgO (100) | 150° C. | 610 | | | |
| Example 15 | 83.5 | 14.8 | 1.7 | SiO2 glass | 150° C. | 680 | | | |
| Example 16 | 83.5 | 14.8 | 1.7 | MgO (100) | 150° C. | 670 | | | |
| Example 17 | 73.7 | 24.4 | 1.9 | SiO2 glass | 150° C. | 680 | 44.76 | 2.86 | 1.3 |
| Example 18 | 73.7 | 24.4 | 1.9 | MgO (100) | 150° C. | 670 | | | |
| Example 19 | 64.1 | 34.2 | 1.7 | SiO2 glass | 150° C. | 620 | 44.80 | 2.86 | 1.5 |
| Example 20 | 64.1 | 34.2 | 1.7 | MgO (100) | 150° C. | 610 | | | |

The thickness of the film excluding the Ru protective film was 520 to 550 Å in Examples 1 to 12 and 610 to 680 Å in Examples 13 to 20. These are values obtained by subtracting the design thickness of the Ru protective layer from the film thickness obtained by X-ray reflectometry.

In Examples 1, 3, 5, 7, 9, 11, 17, and 19 in which the film was formed on a SiO₂ glass substrate, the X-ray diffraction pattern of the sample measured within the 2θ range of 25° to 90° had only one diffraction peak from the Fe—Al alloy magnetic thin film. This peak was found near 44° and was assigned to the (110) plane of the body-centered cubic structure. Since peaks assigned to unreacted Fe and Al were absent, it was presumed that the elements of the respective layers in the sample had diffused with each other to form an Fe—CO—Al alloy. Presumably due to alloy formation, the lattice constant showed a tendency to decrease with the increasing Co content. The crystallite size was as small as 150 Å or less in all of these samples.

These results demonstrated that in the above-described examples in which a film was formed by a multilayer film method, a solid solution of Fe—Al or Fe—Co—Al was formed, the crystals were as fine as 150 Å or less, and the <110> direction of the crystals was perpendicular to the substrate surface.

In even-numbered examples in which a film was formed on a MgO(100) substrate, the (100) peak could not be detected since it overlapped the MgO(200) peak but these examples presumably had the same orientation and crystal grain size as those of Examples 1, 3, 5, and 7.

The films of Examples 13 and 15, which were formed on a SiO₂ substrate, had neither the (110) peak of the body-centered cubic structure nor other peaks. Since the films of Examples 14 and 16 formed on a MgO(100) substrate had the same compositions as Examples 13 and 15, respectively, it is possible that Examples 14 and 16 also do not have the peak assigned to the (110) plane of the body-centered cubic structure.

### Magnetic Property Evaluation

A hysteresis loop at a maximum applied magnetic field of 10 kOe was measured with a vibrating sample magnetometer (VSM) and the coercive force at room temperature was determined. The ferromagnetic resonance (FMR) within the plane of the thin film was measured in the frequency range of 12 to 66 GHz and the DC magnetic field intensity range of 0 to 16.5 kOe. The linewidth at each frequency was determined from the measurement results. The relationship between the resonance frequency and the linewidth was determined by linear least squares data fitting and the damping parameter α was determined. The results are shown in Table 2.

TABLE 2

| | Fe | Co | Al | | Substrate | Ms | Hc | |
|---|---|---|---|---|---|---|---|---|
| | (at %) | (at %) | (at %) | Substrate | heating | (emu/cc) | (Oe) | α |
| Example 1 | 98.2 | 0.0 | 1.8 | SiO2 glass | Ambient | 1575 | 8 | 0.0035 |
| Example 2 | 98.2 | 0.0 | 1.8 | MgO (100) | Ambient | 1563 | 8 | 0.0037 |
| Example 3 | 91.1 | 7.4 | 1.6 | SiO2 glass | Ambient | 1693 | 16 | 0.0038 |
| Example 4 | 91.1 | 7.4 | 1.6 | MgO (100) | Ambient | 1699 | 14 | 0.0035 |
| Example 5 | 80.4 | 17.9 | 1.7 | SiO2 glass | Ambient | 1739 | 50 | 0.0027 |
| Example 6 | 80.4 | 17.9 | 1.7 | MgO (100) | Ambient | 1752 | 43 | 0.0021 |
| Example 7 | 73.8 | 24.4 | 1.8 | SiO2 glass | Ambient | 1741 | 75 | 0.0017 |
| Example 8 | 73.8 | 24.4 | 1.8 | MgO (100) | Ambient | 1742 | 75 | 0.0017 |
| Example 9 | 68.6 | 29.8 | 1.6 | SiO2 glass | Ambient | 1720 | 85 | 0.0090 |
| Example 10 | 68.6 | 29.8 | 1.6 | MgO (100) | Ambient | 1801 | 64 | 0.0042 |
| Example 11 | 64.7 | 33.8 | 1.5 | SiO2 glass | Ambient | 1553 | 101 | 0.0043 |
| Example 12 | 64.7 | 33.8 | 1.5 | MgO (100) | Ambient | 1627 | 69 | 0.0033 |
| Example 13 | 98.4 | 0.0 | 1.6 | SiO2 glass | 150° C. | 1183 | 4 | 0.0058 |
| Example 14 | 98.4 | 0.0 | 1.6 | MgO (100) | 150° C. | 1182 | 4 | 0.0047 |
| Example 15 | 83.5 | 14.8 | 1.7 | SiO2 glass | 150° C. | 1292 | 13 | 0.0042 |
| Example 16 | 83.5 | 14.8 | 1.7 | MgO (100) | 150° C. | 1323 | 11 | 0.0041 |
| Example 17 | 73.7 | 24.4 | 1.9 | SiO2 glass | 150° C. | 1432 | 50 | 0.0035 |
| Example 18 | 73.7 | 24.4 | 1.9 | MgO (100) | 150° C. | 1466 | 22 | 0.0036 |
| Example 19 | 64.1 | 34.2 | 1.7 | SiO2 glass | 150° C. | 1386 | 75 | 0.0027 |
| Example 20 | 64.1 | 34.2 | 1.7 | MgO (100) | 150° C. | 1473 | 15 | 0.0070 |

Samples of Examples 1 to 12 prepared without heating the substrate exhibited a relatively high saturation magnetization Ms even in Examples 1 and 2 free of Co. However, Examples 3 to 12 that contained Co exhibited higher Ms than Examples 1 and 2 and Ms is highest at about a Co content of 24% to 30%. Even in Examples 1 and 2 that did not contain Co, the damping parameter α was satisfactorily low, namely, comparable to or lower than the 0.003 and 0.0043 described in the aforementioned non-patent document obtained by excluding the structural external factors of the Fe thin films. Addition of Co and increasing the Co content further decreased α , and the lowest α value was obtained at about a Co content of 24%. Hc has a tendency to increase with the increase in Co content but in all of these examples, Hc is suppressed to a low value of about 100 Oe or less.

For samples prepared by heating the substrate as in Examples 13 to 20, the Co-content-dependence of Ms, Hc, and α has the same tendency. Heating the substrate dramatically decreases Hc. In Examples 13 to 20, Ms decreased and α increased. However, improvement is possible if the heating method is changed and the base pressure before film deposition is decreased as much as possible to minimize impurity contamination.

Examples described above showed that the Fe—Al alloy magnetic thin film according to the present invention had high magnetization, low coercive force, and a small damping parameter, which make the thin film suitable for high-frequency electronic parts. Addition of Co to the Fe—Al alloy magnetic thin film further increases the magnetization. Furthermore, presumably because the thin film has an average crystallite size not larger than the critical single-domain grain size and the <110> direction of the crystals is perpendicular to the substrate surface, the damping parameter and the coercive force are decreased. The coercive force is further improved when the substrate is heated.

The dependence of saturation magnetization Ms, coercivity Hc, and damping parameter α on film thickness was evaluated for films with the composition of Fe_{73.6}Co_{24.8}Al_{1.6} deposited onto fused silica or MgO(100) substrates at an ambient temperature. (The preparation is described above for Examples 3-12 and 15-20.) Data is provided in Table 3. The examples indicate low α values, lower than 0.007. Especially, the a for Example 27 and 39 with the film thickness of about 820 Å exhibit extremely low value of about 0.0005.

TABLE 3

| | Sub- | Substrate | Thickness | Mₛ | H_{c} | |
|---|---|---|---|---|---|---|
| | strate | heating | (Å) | (emu/cc) | (Oe) | α |
| Example 21 | Fused | Ambient | 112 | 1559 | 14 | 0.0048 |
| Example 22 | silica | | 227 | 1615 | 38 | 0.0021 |
| Example 23 | | | 367 | 1573 | 56 | 0.0030 |
| Example 24 | | | 483 | 1495 | 64 | 0.0061 |
| Example 25 | | | 595 | 1588 | 58 | 0.0028 |
| Example 26 | | | 733 | 1547 | 57 | 0.0012 |
| Example 27 | | | 829 | 1538 | 41 | 0.0004 |
| Example 28 | | | 847 | 1553 | 54 | 0.0009 |
| Example 29 | | | 888 | 1530 | 38 | 0.0034 |
| Example 30 | | | 907 | 1521 | 38 | 0.0032 |
| Example 31 | | | 999 | 1502 | 40 | 0.0049 |
| Example 32 | | | 1196 | 1599 | 42 | 0.0026 |
| Example 33 | MgO | | 116 | 1506 | 11 | 0.0038 |
| Example 34 | (100) | | 230 | 1547 | 30 | 0.0024 |
| Example 35 | | | 367 | 1539 | 52 | 0.0017 |
| Example 36 | | | 497 | 1440 | 51 | 0.0025 |
| Example 37 | | | 596 | 1532 | 55 | 0.0018 |
| Example 38 | | | 736 | 1526 | 54 | 0.0011 |
| Example 39 | | | 821 | 1581 | 40 | 0.0006 |
| Example 40 | | | 853 | 1519 | 53 | 0.0010 |
| Example 41 | | | 888 | 1541 | 39 | 0.0028 |
| Example 42 | | | 906 | 1528 | 40 | 0.0045 |
| Example 43 | | | 998 | 1503 | 40 | 0.0066 |
| Example 44 | | | 1199 | 1552 | 38 | 0.0013 |

Other advantages which are obvious and which are inherent to the invention will be evident to one skilled in the art. It will be understood that certain features and sub-combinations are of utility and may be employed without reference to other features and sub-combinations. This is contemplated by and is within the scope of the claims. Since many possible examples may be made of the invention without departing from the scope thereof, it is to be understood that all matter herein set forth or shown in the accompanying drawings is to be interpreted as illustrative and not in a limiting sense.

1. An Fe—Al alloy magnetic thin film, comprising: in terms of atomic ratio, 0% to 35% of Co; and 1.5% to 2% of Al, wherein a <110> direction of a crystal contained in a material is perpendicular to a substrate surface and a crystallite size is 150 Å or less.

2. The alloy magnetic thin film of claim 1, wherein the amount of Co is 0%.

3. The alloy magnetic thin film of claim 1, wherein Co is present at from 5% to 15%.

4. The alloy magnetic thin film of claim 1, wherein Co is present at from 10% to 20%.

5. The alloy magnetic thin film of claim 1, wherein Co is present at from 15% to 25%.

6. The alloy magnetic thin film of claim 1, wherein Co is present at from 20% to 30%.

7. The alloy magnetic thin film of claim 1, wherein Co is present at from 25% to 35%.

8. The alloy magnetic thin film of claim 1, wherein the substrate comprises a metal, glass, silicon, or ceramic.

9. The alloy magnetic thin film of claim 1, wherein the substrate comprises MgO or SiO₂.

10. The alloy magnetic thin film of claim 1, wherein the crystallite size is 140 Å or less.

11. (canceled)

12. (canceled)

13. The alloy magnetic thin film of claim 1, further comprising a protective layer comprising Mo, W, Ru, or Ta on top of the thin film.

14. The alloy magnetic thin film of claim 1, wherein the thin film comprises a plurality of Al layers.

15. The alloy magnetic thin film of claim 14, wherein the Al layers are each 0.4 Å thick.

16. The alloy magnetic thin film of claim 1, wherein the thin film comprises a plurality of Fe or Fe—Co layers.

17. The alloy magnetic thin film of claim 16, wherein the Fe or Fe—Co layers are each from 0 to 1.8 Å thick.

18. A method of preparing an Fe—Al alloy magnetic thin film, comprising:
depositing a target material comprising one or more of Fe, Co, and Al onto a substrate by sputtering,
wherein the Fe—Al alloy magnetic thin film comprises, in terms of atomic ratio, 0% to 35% of Co; and 1.5% to 2% of Al, wherein a <110> direction of a crystal contained in a material is perpendicular to the substrate surface and with a crystallite size is 150 Å or less.

19. The method of claim 18, wherein the target material is chosen from Fe, Co, Al, Fe—Co—Al alloy, Fe—Co alloy, Fe—Al alloy, and Co—Al alloy.

20. The method of claim 18, wherein the substrate is heated during sputtering.

21. The method of claim 18, wherein the substrate is at ambient temperature during sputtering.

22. The method of claim 18, wherein the substrate comprises a metal, glass, silicon, or ceramic.

23. The method of claim 18, wherein the substrate comprises MgO or SiO₂.

24. The method of claim 18, further comprising providing a protective layer of Mo, W, Ru, or Ta on top of the magnetic thin film.

25. The method of claim 18, wherein the sputtering is magnetron sputtering.
